(19) United States
(12) Patent Application Publication
(10) Pub. No.: US 2026/0213118 A1
(43) Pub. Date: Jul. 23, 2026

(54) CHARGED PARTICLE BEAM INSPECTION APPARATUS AND METHOD

(71) Applicant: ASML Netherlands B.V., Veldhoven (NL)

(72) Inventors: Xiaoyu JI, San Jose, CA (US); Datong ZHANG, San Jose, CA (US); Weiming REN, San Jose, CA (US); Xuechen ZHU, San Jose, CA (US)

(73) Assignee: ASML Netherlands B.V., Veldhoven (NL)

(21) Appl. No.: 19/141,530

(22) PCT Filed: Dec. 13, 2023
(86) PCT No.: PCT/EP2023/085707

§ 371 Date: Jun. 20, 2025

Related U.S. Application Data
(60) Provisional application No. 63/434,338, filed on Dec. 21, 2022.

(51) Int. Cl. H01J 37/145; H01J 37/12; H01J 37/14; H01J 37/147

(52) U.S. Cl. CPC H01J 37/145; H01J 37/12; H01J 37/14; H01J 37/1477

(57) ABSTRACT

A charged particle beam inspection apparatus and charged particle beam adjustment technology, and more particularly, a charged particle beam contactless electrical characterization technology is disclosed. A charged particle beam apparatus may be used to rapidly vary charged particle beam parameters to determine electrical characteristics of a sample without direct contact. The disclosed charged particle beam contactless electrical characterization technology may be applied as defect detection.

### CROSS-REFERENCE TO RELATED APPLICATIONS

This application claims priority of U.S. application 63/434,338 which was filed on Dec. 21, 2022 and which is incorporated herein in its entirety by reference.

### FIELD

The embodiments provided herein disclose a charged particle beam inspection apparatus and charged particle beam adjustment technology, and more particularly, a contactless electrical characterization technology using a charged particle beam inspection apparatus. A charged particle beam apparatus may be used to rapidly vary charged particle beam parameters to determine electrical characteristics of a sample without direct contact.

### BACKGROUND

In manufacturing processes of integrated circuits (ICs), unfinished or finished circuit components are inspected to ensure that they are manufactured according to design, are free of defects, and have desirable electrical properties. Inspection systems utilizing optical microscopes or charged particle (e.g., electron) beam microscopes, such as a scanning electron microscope (SEM) can be employed. As the physical sizes of IC components continue to shrink, accuracy and yield in IC inspection become increasingly important. In a SEM, a beam of primary electrons having a relatively high energy is decelerated to land on a sample at a relatively low landing energy and is focused to form a probe spot thereon. Due to this focused probe spot of primary electrons, secondary electrons will be generated from the surface. The secondary electrons are detected by an electron detector to generated SEM images of the sample.

Inspection images such as SEM images can be used to identify or classify a defect(s) of the manufactured ICs. For inspection of electrical properties of the small IC device structures, a SEM may apply an electrical signal to a sample and measure a corresponding response. However, rapid adjustment of electron beam current and focus is required to generate an I-V curve for a sample. To improve defect detection and electrical property investigation, an inspection tool and method that can increase throughput and maintain IC structural fidelity is desired.

### SUMMARY

The embodiments provided herein disclose a charged particle beam system for inspecting a sample, and more particularly, a charged particle beam system for inspecting a sample including an improved and rapid focus compensation mechanism.

Some embodiments provide a charged particle beam apparatus for inspecting a sample. The apparatus comprises a charged particle source configured to emit a primary charged particle beam, a first lens configured to manipulate the primary charged particle beam to adjust a probe current of the primary charged particle beam, an objective lens configured to focus the primary charged particle beam to a focal point substantially on a surface of the sample, a second lens configured to generate an electrostatic field that substantially overlaps with a magnetic field generated by the objective lens and also to compensate for a focus variation caused by a change in probe current without changing a focusing power of the objective lens, wherein the change in probe current is caused by the first lens, and a deflector configured to deflect the primary charged particle beam to scan a scan line of a field of view of the sample.

In some embodiments, a non-transitory computer readable medium storing a set of instructions that is executable by one or more processors of a charged particle beam apparatus to cause the charged particle beam apparatus to perform a method of inspecting a sample is provided. The method comprises manipulating, with a first lens, a primary charged particle beam emitted by a charged particle source to change a current of the primary charged particle beam to a first probe current, focusing, with an objective lens, the primary charged particle beam at the first probe current to a focal point substantially at a surface of the sample, scanning a first scan line of a field of view of the sample with the primary charged particle beam at the first probe current, after scanning the first scan line, manipulating, with the first lens, the primary charged particle beam to change the current of the primary charged particle beam to a second probe current, compensating, with a second lens, a focus variation of the primary charged particle beam at the second probe current without changing a setting of the objective lens, and scanning a second scan line of a field of view with the primary charged particle beam at the second probe current, wherein scanning of the first line and scanning of the second line are performed sequentially.

Other advantages of the present disclosure will become apparent from the following description taken in conjunction with the accompanying drawings wherein are set forth, by way of illustration and example, certain embodiments of the present disclosure.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an example charged particle beam inspection system, consistent with embodiments of the present disclosure.

FIG. 2 is a schematic diagram illustrating an example charged particle beam tool, consistent with embodiments of the present disclosure.

FIG. 3 is an example graph showing a yield of secondary electrons relative to landing energy of primary electrons.

FIG. 4 is a schematic diagram illustrating a voltage-contrast response of a sample upon an electron beam impacting the sample.

FIG. 5 is a schematic diagram illustrating an example charged particle beam apparatus for inspecting electrical characteristics of a sample, consistent with embodiments of the present disclosure.

FIG. 6 is a schematic diagram illustrating example scan lines of a focused electron beam across a sample surface applied by a charged particle beam apparatus, consistent with embodiments of the present disclosure.

FIG. 7 is a schematic diagram of a top portion of an example charged-particle beam apparatus comprising a stigmator, consistent with embodiments of the present disclosure.

FIG. 8 is a flowchart representing an example process for compensating charged particle beam focus, consistent with embodiments of the present disclosure.

FIG. 9 is a flowchart representing an example process for inspecting an electrical characteristic of a sample without direct contact, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

The enhanced computing power of electronic devices, while reducing the physical size of the devices, can be accomplished by significantly increasing the packing density of circuit components such as transistors, capacitors, diodes, etc. on an IC chip. For example, an IC chip of a smart phone, which is the size of a thumbnail, may include over 2 billion transistors, the size of each transistor being less than 1/1000th of a human hair. Thus, it is not surprising that semiconductor IC manufacturing is a complex and time-consuming process, with hundreds of individual steps. Errors in even one step have the potential to dramatically affect the functioning of the final product. Even one “killer defect” can cause device failure. The goal of the manufacturing process is to improve the overall yield of the process. For example, for a 50-step process to get to a 75% yield, each individual step must have a yield greater than 99.4%, and if the individual step yield is 95%, the overall process yield drops to 7%.

While high process yield is desirable in an IC chip manufacturing facility, maintaining a high wafer throughput, defined as the number of wafers processed per hour, is also essential. High process yields and high wafer throughput can be impacted by the presence of defects, especially if operator intervention is required for reviewing the defects. Thus, high throughput detection and identification of micro and nano-sized defects by inspection tools (such as a SEM) is essential for maintaining high yields and low cost.

A SEM scans the surface of a sample with a focused beam of electrons. The electrons interact with the sample and generate secondary electrons. By scanning the sample with an electron beam and capturing the secondary electrons with a detector, a SEM creates an image of the sample that shows the internal device structure under the area of the sample being inspected. A conventional SEM inspection tool obtains a single image of an area of a sample and compares the obtained image against a reference image that represents the corresponding device structures absent any defect. A difference detected from the comparison of the images may indicate a defect in the sample.

A nanoprobing technique may be used with a SEM to obtain an electrical characteristic (e.g., resistance, capacitance, etc.) of a sample. For example, a SEM may apply an electrical signal via an electron beam impacting a sample and measure a corresponding electrical response, and therefore determine an electrical characteristic or property of the sample. To holistically analyze the electrical properties of a sample, an electric current and voltage relationship (e.g., I-V curve) may be generated by adjusting the current of the electron beam in an SEM to elicit different electrical responses of the sample. However, conventional SEM systems are unable to support rapid adjustments to electron beam current because of the slow adjustment process. Therefore, the ability to extract certain I/V information is undesirably limited, as users are not able to, for example, rapidly scan a node multiple times in quick succession with a different probe current for each scan.

Embodiments of the present disclosure may provide an electron beam inspection apparatus to scan a sample multiple times in quick succession with different electron beam parameters, which enables the determination of electrical characteristics or properties of a sample (e.g., I-V curve) without direct contact. Embodiments of the present disclosure may provide an electrostatic lens that may rapidly compensate focus of an electron beam when the current of the electron beam is adjusted. The objective lens may be kept constant during this focus adjustment, so less energy and time is required to focus the electron beam onto a sample and therefore measure an electrical characteristic or property of the sample. The electron beam inspection apparatus disclosed may therefore be able to support rapid electron beam parameter adjustment and determine an I-V curve for a sample that would be unobtainable without such rapid electron beam parameter adjustment. For ease of explanation without causing ambiguity, electrons are used as examples in descriptions herein. However, it should be noted that any charged particle may be used in any embodiment of this disclosure, which is not limited to electrons.

Relative dimensions of components in drawings may be exaggerated for clarity. Within the following description of drawings the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a database can include A or B, then, unless specifically stated otherwise or infeasible, the database can include A, or B, or A and B. As a second example, if it is stated that a database can include A, B, or C, then, unless specifically stated otherwise or infeasible, the database can include A, or B, or C, or A and B, or A and C, or B and C, or A and B and C.

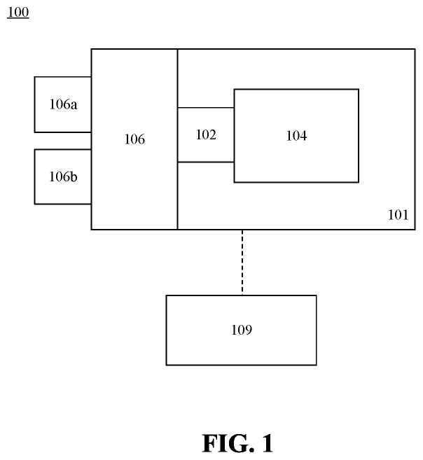

Reference is now made to FIG. 1, which is a schematic diagram illustrating an exemplary charged particle beam inspection system 100, consistent with embodiments of the present disclosure. As shown in FIG. 1, charged particle beam inspection system 100 includes a main chamber 101, a load lock chamber 102, an electron beam tool 104, and an equipment front end module (EFEM) 106. Electron beam tool 104 is located within main chamber 101. While the description and drawings are directed to an electron beam, it is appreciated that the embodiments are not used to limit the present disclosure to specific charged particles.

EFEM 106 includes a first loading port 106a and a second loading port 106b. EFEM 106 may include additional loading port(s). First loading port 106a and second loading port 106b may, for example, receive sample front opening unified pods (FOUPs) that contain sample (e.g., semiconductor wafers or wafers made of other material(s)) or samples to be inspected (wafers and samples are collectively referred to as “samples” hereafter). One or more robot arms (not shown) in EFEM 106 transport the samples to load lock chamber 102.

Load lock chamber 102 may be connected to a load lock vacuum pump system (not shown), which removes gas molecules in load lock chamber 102 to reach a first pressure below the atmospheric pressure. After reaching the first pressure, one or more robot arms (not shown) transport the sample from load lock chamber 102 to main chamber 101. Main chamber 101 is connected to a main chamber vacuum pump system (not shown), which removes gas molecules in main chamber 101 to reach a second pressure below the first pressure. After reaching the second pressure, the sample is subject to inspection by electron beam tool 104. In some embodiments, electron beam tool 104 may comprise a single beam electron inspection tool.

A controller 109 is electronically connected to electron beam tool 104. Controller 109 may be a computer configured to execute various controls of charged particle beam inspection system 100. While controller 109 is shown in FIG. 1 as being outside of the structure that includes main chamber 101, load lock chamber 102, and EFEM 106, it is appreciated that controller 109 may be part of the structure. While the present disclosure provides examples of main chamber 101 housing an electron beam inspection tool, it should be noted that aspects of the disclosure in their broadest sense are not limited to a chamber housing an electron beam inspection tool. Rather, it is appreciated that the foregoing principles may also be applied to other tools that operate under the second pressure.

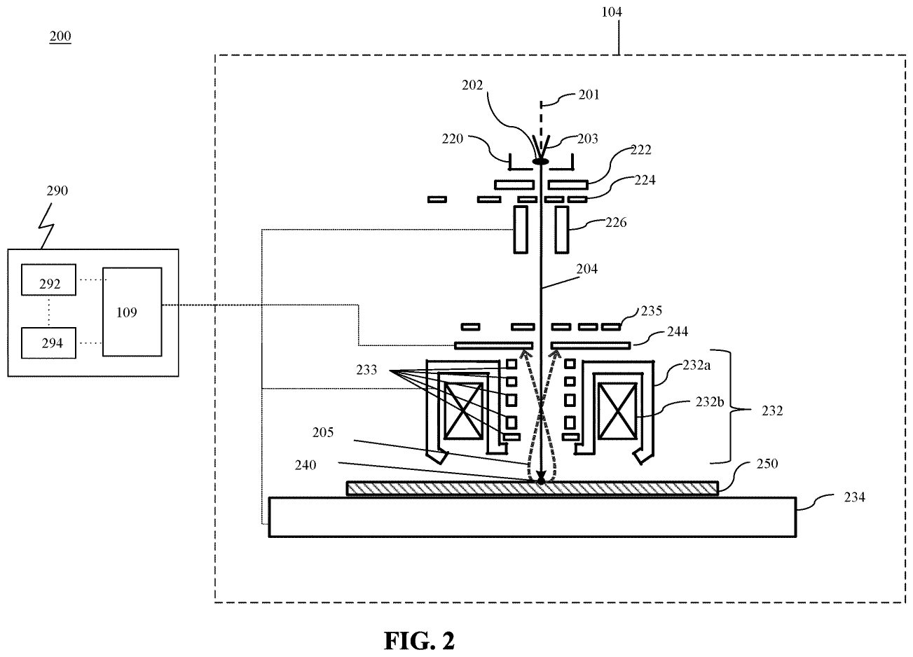

Reference is now made to FIG. 2, which is a schematic diagram illustrating an example imaging system 200, comprising an electron beam tool 104 and an image processing system 290, consistent with embodiments of the present disclosure. As shown in FIG. 2, electron beam tool 104 may include a motorized stage 234 to support a sample 250 to be inspected. Electron beam tool 104 may further include an objective lens 232, electron detector 244 (which includes electron sensor surfaces), a condenser lens 226, a Coulomb aperture 224, a gun aperture 222, an anode 220, and a cathode 203, one or more of which may be aligned with an optical axis 201 of electron beam tool 104. In some embodiments, detector 244 may be arranged off optical axis 201.

Objective lens 232, may include a modified swing objective retarding immersion lens (SORIL), which may include an objective lens body 232a, and an objective exciting coil 232b. Within objective lens 232 may be a deflector or a set of deflectors 233. Electron beam tool 104 may additionally include an energy dispersive X-ray spectrometer (EDS) detector (not shown) to characterize the materials on the sample.

A primary electron beam 204 may be emitted from cathode 203 by applying a voltage between anode 220 and cathode 203. Primary electron beam 204 may pass through gun aperture 222 and Coulomb aperture 224, both of which may determine the current of primary electron beam 204 entering condenser lens 226, which resides below Coulomb aperture 224. Condenser lens 226 may focus primary electron beam 204 before the beam enters current-limiting aperture 235 to set the current of the electron beam before entering objective lens 232. The set current of primary electron beam 204 entering objective lens 232 may be referred to as the probe current.

Objective lens 232 may focus primary electron beam 204 onto sample 250 for inspection and can form a probe spot 240 on surface of sample 250. Deflector(s) 233 may deflect primary electron beam 204 to scan probe spot 240 over sample 250. For example, in a scanning process, deflector(s) 233 may be controlled to deflect primary electron beam 204 sequentially onto different locations of top surface of sample 250 at different time points, to provide data for image reconstruction for different parts of sample 250. Moreover, deflectors 233 may also be controlled to deflect primary electron beam 204 onto different sides of sample 250 at a particular location, at different time points, to provide data for stereo image reconstruction of the sample structure at that location.

When an electric signal is applied to objective exciting coil 232b, an axially-symmetric (i.e., symmetric around optical axis 201) magnetic field may be generated in the sample surface area. A part of sample 250 being scanned by primary electron beam 204 may be immersed in the magnetic field. Different voltages may be applied onto sample 250 to generate an axial symmetric retarding electrostatic field near the sample surface. The electrostatic field may reduce the energy of impinging primary electron beam 204 near the surface of the sample before electrons of the beam collide with sample 250.

Secondary electrons 205 may be emitted from the part of sample 250 upon receiving primary electron beam 204. While not illustrated in FIG. 2, it is appreciated that primary electron beam 204 impacting sample 250 may also generate backscattered electrons or Auger electrons. Secondary electrons 205 may be received by sensor surfaces of electron detector 244. In some embodiments, electron detector 244 may generate a signal (e.g., a voltage, a current, etc.) that represents an intensity of emitted secondary electrons 205 and may provide the signal to image processing system 290 in communication with electron detector 244. The intensity of secondary electrons 205 emitted may vary according to the external or internal structure of sample 250, and thus may indicate whether sample 250 includes defects. Moreover, as discussed above, primary electron beam 204 may be projected onto different locations of the top surface of sample 250, or different sides of sample 250 at particular location, to generate secondary electrons 205 of different intensities. Therefore, by mapping the intensity of secondary electrons 205 emitted with the areas of sample 250, image processing system 290 may reconstruct an image that reflects the characteristics of internal or external structures of sample 250.

Imaging system 200 may also comprise image processing system 290 that includes an image acquirer 292, a storage 294, and controller 109. Image acquirer 292 may comprise one or more processors. For example, image acquirer 292 may comprise a computer, server, mainframe host, terminals, personal computer, any kind of mobile computing devices, and the like, or a combination thereof. Image acquirer 292 may be communicatively coupled to a detector 244 of electron beam tool 104 through a medium such as an electrical conductor, optical fiber cable, portable storage media, IR, Bluetooth, internet, wireless network, wireless radio, or a combination thereof. Image acquirer 292 may receive a signal from detector 244 and may construct an image. Image acquirer 292 may thus acquire images of sample 250. Image acquirer 292 may also perform various post-processing functions, such as generating contours, superimposing indicators on an acquired image, and the like. Image acquirer 292 may be configured to perform adjustments of brightness and contrast, etc. of acquired images. Storage 294 may be a storage medium such as a hard disk, flash drive, cloud storage, random access memory (RAM), other types of computer readable memory, and the like. Storage 294 may be coupled with image acquirer 292 and may be used for saving scanned raw image data as original images, and post-processed images. Image acquirer 292 and storage 294 may be connected to controller 109. Image acquirer 292, storage 294, and controller 109 may be integrated together as one control unit.

Image acquirer 292 may acquire one or more images of a sample based on an imaging signal received from detector 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of sample 250. The acquired images may comprise multiple images of a single imaging area of sample 250 sampled multiple times over a time sequence. The multiple images may be stored in storage 294. Image processing system 290 may be configured to perform image processing steps with the multiple images of the same location of sample 250.

Image processing system 290 may include measurement circuitries (e.g., analog-to-digital converters) to obtain a distribution of the detected secondary electrons. The electron distribution data collected during a detection time window, in combination with corresponding scan path data of primary electron beam 204 incident on the sample surface, can be used to reconstruct images of the sample structures under inspection. The reconstructed images can be used to reveal various features of the internal or external structures of sample 250, and thereby can be used to reveal any defects that may exist in the sample.

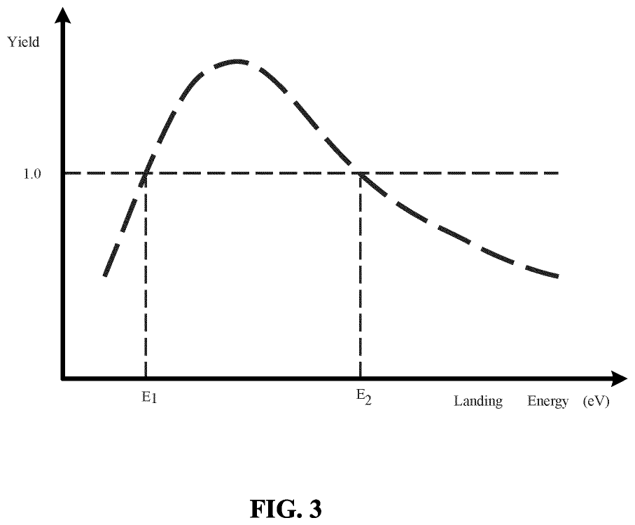

Reference is now made to FIG. 3, which is an example graph showing a yield of emitted secondary electrons relative to landing energy of primary electrons. The graph illustrates the relationship of the landing energy, or current, of a primary electron beam (such as primary electron beam 204 in FIG. 2) and a yield of emitted secondary electrons (such as secondary electrons 205 in FIG. 2). The yield of emitted secondary electrons indicates how many secondary electrons are emitted in response to the primary electrons impacting a sample surface. For example, a yield greater than 1.0 indicates that a larger number of secondary electrons may be emitted from the surface of a sample compared to the number of primary electrons that impact the sample. Similarly, a yield lower than 1.0 indicates that a lesser number of secondary electrons may be emitted in response to the primary electrons impacting the sample.

As shown in the graph of FIG. 3, when the landing energy of the primary electrons is within a range from E1 to E2, more secondary electrons may be emitted from the surface of the sample than primary electrons that impact the surface, therefore resulting in a positive electrical potential, or voltage, at the surface of the sample. A sample with more positive surface potential may produce a darker voltage contrast image because a detector may receive a lesser number of secondary electrons.

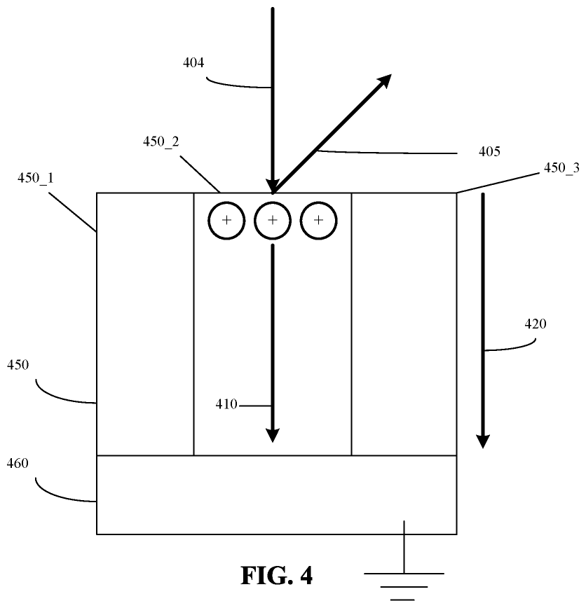

Reference is now made to FIG. 4, which is a schematic diagram illustrating a voltage-contrast response of a sample upon a primary electron beam impacting the sample, consistent with embodiments of the present disclosure. When an electron beam tool (such as electron beam tool 104 of FIG. 2) scans the surface of sample 450 with electrons from a primary electron beam 404, secondary electrons 405 (and other species such as backscattered electrons or Auger electrons) may be emitted from the surface. The ratio of the number of emitted secondary electrons 405 to incident electrons impacting surface of sample 450 from primary electron beam 404 determines the yield of emitted secondary electrons as described above. A field of view of sample 450 may have different microstructures 450_1, 450_2, and 450_3. In the example illustrated in FIG. 4, microstructure 450_2 is impacted by primary electron beam 404, and in response, secondary electrons 405 are emitted from sample 450. Secondary electrons 405 may be collected and measured by a detector.

As described above with respect to FIG. 3, by adjusting the landing energy of the primary electron beam (e.g., primary electron beam 404) properly, the emission yield of secondary electrons can be controlled. For example, a proper landing energy between E1 and E2 may be chosen to make the yield of secondary electrons greater than 1, which may result in the surface of sample microstructure 450_2 to be positively charged as shown in FIG. 4. Referring back to FIG. 4, the positively charged top surface of sample microstructure 450_2 creates a voltage difference 420 between the top surface of microstructure 450_2 and a substrate 460 that may be electrically grounded. As a result, a sample current 410 may flow through microstructure 450_2. As discussed in FIG. 3, changing the landing energy a primary electron beam affects the number of the emitted secondary electrons. Referring back to FIG. 4, the landing energy of primary electron beam 404 may be held constant while the probe current of primary electron beam 404 may be varied. This in turn may change the emission yield of secondary electrons and voltage difference 420. Therefore, controlling the probe current of primary electron beam 404 may change voltage difference 420 and sample current 410. The sample current 410 of microstructure 450_2 can be determined as the difference in the probe current of primary electron beam 404 and a current of emitted secondary electrons 405 measured by a detector. An image of sample 450 with microstructure 450_2 may be generated by an image processing system or a controller using signal collected from the detector measuring emitted secondary electrons 405. Voltage contrast of the image may be applied to back calculate the secondary electron yield and voltage difference 420.

Sample characteristics for microstructure 450_2 such as resistance, capacitance, and other electrical properties may be calculated based on the back calculated and measured values. For example, a resistance value may be determined by dividing the calculated sample voltage difference 420 by the calculated sample current 410. The calculated resistance value may be compared to a standard resistance value (e.g., an expected resistance based on the design parameters of the device structure) for the sample as a form of defect detection. A calculated resistance value significantly different than a standard resistance value for the sample may indicate a defect present in the region of the sample imaged. To more thoroughly analyze electrical properties of a sample, the probe current of primary electron beam 404 may be changed such that the yield of emitted secondary electrons is larger than 1, as shown in FIG. 3. Referring back to FIG. 4, the probe current of primary electron beam 404 may be adjusted and primary electron beam 404 may be rescanned across sample 450. This may generate a different yield of emitted secondary electrons and thus generate a second set of values for sample current 410 and sample voltage difference 420 as described above. This may be repeated multiple times in which each probe current may be selected such that a different sample voltage difference can be created each time while maintaining the yields greater than 1. These multiple datapoints may be used to generate an I-V curve that represent an electrical characteristic of microstructure 450_2.

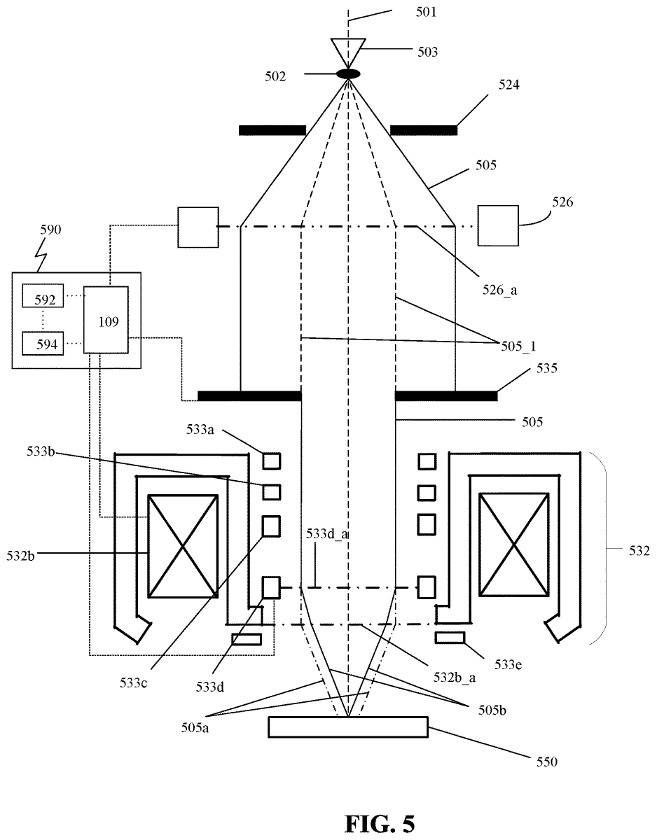

Reference is now made to FIG. 5, which is a schematic diagram illustrating an example charged particle beam apparatus for inspecting electrical characteristics of a sample, consistent with embodiments of the present disclosure. The charged particle beam apparatus may include a cathode 503, a Coulomb aperture 524, a condenser lens 526, a current-limiting aperture 535, an objective lens 532, and a plurality of deflectors 533a-533e. As described above, cathode 503 emits a primary electron beam 505, which passes through Coulomb aperture 524 before entering condenser lens 526. Condenser lens 526 may focus primary electron beam 505 before primary electron beam 504 enters current-limiting aperture 535. Objective lens 532 may then focus primary electron beam 505 onto the surface of a sample 550.

In some embodiments, controller 109 may be communicatively coupled with condenser lens 526, current limiting aperture 535, electron detector (not shown), and objective lens exciting coil 532b to provide an electrical signal (e.g., current, voltage). In some embodiments, controller 109 may be communicatively coupled with deflectors (e.g., deflector 533d) to provide an electrical signal. In some embodiments, condenser lens 526 may be used to control a probe current of primary electron beam 505, which determines the landing energy of primary electrons, as explained above in FIGS. 2 and 3. Controller 109 may provide an electrical signal to condenser lens 526 to generate a magnetic field 526_a, which may provide a focusing effect (e.g., collimate or focus) to manipulate primary electron beam 505. The strength of the electrical signal provided by controller 109 to condenser lens 526 determines the strength of magnetic field 526_a and influences the strength of the focusing effect to primary electron beam 505. As illustrated in FIG. 5, the electrical signal applied to condenser lens 526 focuses primary electron beam 505. Consequently, a concentration of electrons in primary electron beam 505 passes through current limiting aperture 535 to determine a diameter and a corresponding probe current of primary electron beam 505. The dashed lines 505_1 serve as an illustrative pathway the electrons in primary electron beam 505 follow to pass through current limiting aperture 535. The greater the ratio of electrons in primary electron beam 505 that pass through current limiting aperture 535 to electrons in primary electron beam 505 that are blocked, the greater the probe current. It is appreciated that current-limiting aperture 535 may be at a constant width, so condenser lens 526 may control the probe current of primary electron beam 505. It is further appreciated that current-limiting aperture 535 may be adjustable.

Condenser lens 526 may be adjusted to change the probe current of primary electron beam 505. This change in probe current may cause primary electron beam 505 to become out of focus when impacting the surface of sample 550. Objective lens 532 usually needs to be adjusted to refocus primary electron beam 505, but this may often be a slow adjustment as objective lens 532 is a magnetic component. This may therefore decrease throughput of sample analysis. In some embodiments, other components of the example charged particle apparatus shown in FIG. 5 may be used to compensate the focus variation with a change in probe current of primary electron beam 505, without adjusting the focusing power of objective lens 532.

For example, if the electrical signal applied to objective lens exciting coil 532b remains constant and the corresponding magnetic field 532b_a applies a focusing effect of constant strength to primary electron beam 505, even after the focusing effect of condenser lens 526 is varied (e.g., adjusting focus of primary electron beam 505) to increase or decrease the probe current of primary electron beam 505, then objective lens 532 would under-focus or over-focus primary electron beam 505 onto sample 550 (i.e., the focal point would be below sample 550 for an under-focused primary electron beam 505 and above for an over-focused primary electron beam 505). The dash-dotted lines 505a in FIG. 5 illustrate the under focusing situation. To compensate the under-focus or over-focus effects (i.e., focus variations), in some embodiments, deflector 533d may be used as an electrostatic lens. For example, controller 109 may apply a DC bias electrical signal to deflector 533d which may comprise a plurality of electrodes. When a DC bias electrical signal is applied to all electrodes, deflector 533d may function as an electrostatic lens as well as a deflector. Deflector 533d may generate a corresponding electrostatic field 533d_a that can provide a focusing effect to primary electron beam 505 to compensate for the under-focus or over-focus effects caused by the change in the probe current. The solid lines 505b illustrate the compensated (refocused) primary electron beam 505. During this process, the field strength of magnetic field 532b_a may stay the same compared to the condition where only magnetic field 532b_a applies a focusing effect to primary electron beam 505.

Since deflector 533d is positioned relatively close to magnetic field 532b_a, there may be overlap between the distribution of electrostatic field 533d_a and the distribution of magnetic field 532b_a, which may minimally impact fluctuations to primary electron beam 505 magnification and resolution. Adjusting the setting of a magnetic lens is typically slower than an electrostatic lens, so compensating focus with deflector 533d instead of changing magnetic objective lens 532 may minimally impact throughput. Since deflector 533d functions as an electrostatic lens, changing field strength of electrostatic field 533d_a may be quicker than changing field strength of magnetic field 532b_a from objective lens 532 to compensate focus when adjusting probe current. In some embodiments, deflector 533d may have a small inner diameter so the required electrical signal to compensate focus is lower than an electrical signal required to adjust objective lens 532. This may help to achieve a fast focus compensation. In some embodiments, the electrical signal applied to deflector 533d to compensate focus of primary electron beam 505 may not interfere with a deflection function of deflector 533d, so deflector 533d functions an electrostatic lens as well as a deflector. In some embodiments, deflector 533d used for focus compensation may be separate from scanning deflectors, such as deflectors 533b or 533c, when performing local measurements with a small field of view.

Although FIG. 5 describes an embodiment using deflector 533d to compensate the over-focus or under-focus effect, it is appreciated that other components could be utilized for the compensation. For example, in some embodiments, instead of deflector 533d, a deflector positioned below the objective lens (e.g., deflector 533e or an objective lens control electrode (not shown)) may be used to compensate the over-focus or under-focus effects. Since deflector 533e is positioned closer to sample 550 than deflector 533d, the electrical signal applied to deflector 533e to compensate the focus may not need to be as strong compared the electrical signal applied to deflector 533d. In some embodiments, both deflector 533d and 533e may be used to compensate the over-focus or under-focus effects. Using both deflector 533d and 533e may require even smaller electrical signals thus reducing required energy input to compensate focus for primary electron beam 505 when probe current is adjusted. Additionally, a larger adjustment in probe current of primary electron beam 505 may require a large amount of focus compensation, and accordingly both deflector 533d and 533e may be used.

Furthermore, although condenser lens 526 may be a magnetic lens as discussed above, it is appreciated that other configurations for condenser lens 526 may be utilized. For example, in some embodiments, condenser lens 526 may be an electrostatic lens. In embodiments where condenser lens 526 may be an electrostatic lens, adjusting probe current (with condenser lens 526) and compensating focus (with deflector 533d, 533e, or both) may be entirely an electrostatic controlled process that can be faster than using a magnetic component. In some embodiments, condenser lens 526 may be a compound magnetic and electrostatic lens used in combination with deflectors 533d, 533e, or both as described above. In some embodiments, the magnetic component of the condenser lens may be kept the same, while the electrostatic component may be varied to adjust the probe current and increase throughput of adjusting probe current and compensating focus described above.

The focused primary electron beam 505 impacting sample 550 may emit corresponding secondary electrons that may be collected and measured by a corresponding detector (not shown). An image processing system 590 may then generate an image of sample 550 based on intensities of collected secondary electron signals. If the probe current is selected such that a yield of secondary electrons is greater than 1, then a processing system (e.g., image processing system 590) may calculate a corresponding voltage difference and current of sample 550, and then determine an electrical characteristic of sample 550 as described above for FIG. 4.

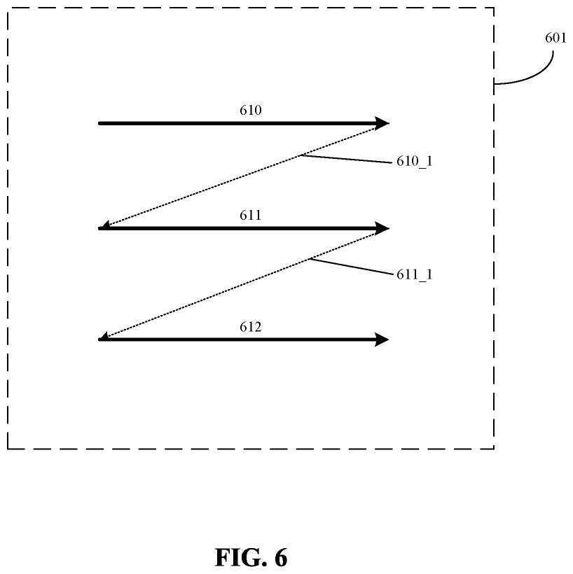

Reference is now made to FIG. 6, which is a schematic diagram illustrating various scan lines of a primary electron beam across a sample surface applied by a charged particle beam apparatus (such as the charged particle beam apparatus shown in FIG. 5), consistent with embodiments of this present disclosure. FIG. 6 illustrates a top-view field of view 601 of a sample, in which a primary electron beam is scanned across field of view 601 as a scan line for a time interval. Deflectors, such as deflectors 553a-553e in FIG. 5, may deflect the focused primary electron beam. Referring back to FIG. 6, a time interval for a first scan line 610, a second scan line 611, and a third scan line 612 may each be from 10 μs to 100 μs, inclusive. In some embodiments, the primary electron beam is adjusted to have a first probe current and scan first scan line 610 for a first time interval. Before scanning, the electron beam may be focused by an objective lens, which may be communicatively coupled with a processor to apply and record an electrical signal to generate a magnetic field to focus the electron beam at the first probe current value. After first scan line 610 is completed, the probe current of the primary electron beam may be adjusted, and primary electron beam may be focus compensated by a deflector as described above. The refocused primary electron may be repositioned to a different location as illustrated by trace line 610_1, where the primary electron beam may then be rescanned across the sample at the different probe current as shown by scan line 611. Similarly, the probe current of the primary electron beam may be adjusted and scanned a third time as shown by scan line 612. It is appreciated that FIG. 6 is for illustrative purposes and the width, length, and number of scan lines 610, 611, and 612 are not so limited. It is further appreciated that multiple lines may be scanned on a sample at a first probe current before adjusting to a second probe current. Each probe current may be selected such that a yield of secondary electrons is greater than 1. During each time interval, secondary electrons are emitted and collected by a corresponding detector to generate a corresponding image for each scan line. An image processing system may back calculate corresponding electrical characteristics of the sample field of view 601 as discussed above in FIG. 4. Thus, the charged particle beam apparatus acts as a contactless probe to determine electrical characteristics of the sample field of view 601.

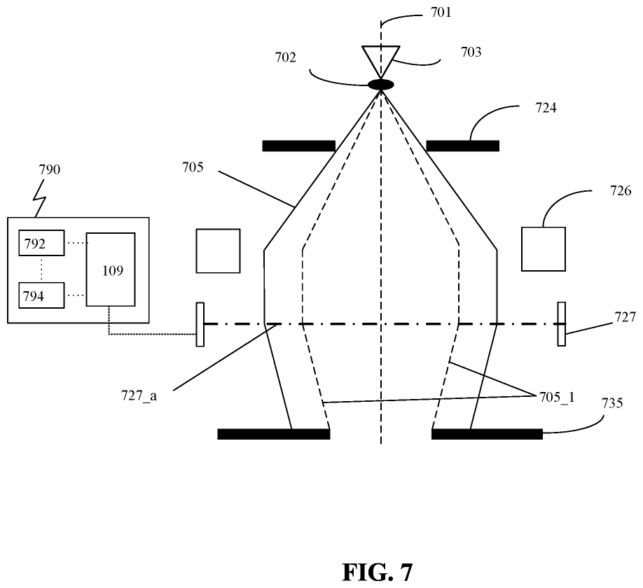

Reference is now made to FIG. 7, which is a schematic diagram of a top portion of a charged-particle beam apparatus with a stigmator, consistent with embodiments of the present disclosure. A stigmator may be configured to impose a weak electric or magnetic field onto a primary electron beam to reduce an astigmatism of the primary electron beam. In some embodiments, instead of a condenser lens, a stigmator may be used to apply a focusing effect to the primary electron beam to change the probe current of the primary electron beam. In some embodiments, stigmator 727 may comprise a plurality of electrodes. Stigmator 727 may be communicatively coupled with controller 109 in which an electric signal is applied to stigmator 727, as discussed above for condenser lens 526 in FIG. 5. Stigmator 727 may generate a corresponding electrostatic field 727_a that may apply a focusing effect to manipulate primary electron beam 705. In some embodiments, the focusing effect of condenser lens 726 may remain constant when stigmator 727 may be configured to be an electrostatic lens. While FIG. 7 illustrates a specific focusing effect of condenser lens 726, it is appreciated that condenser lens 726 may apply any focusing effect to primary electron beam 705 but will remain constant while a probe current may be varied by stigmator 727. While FIG. 7 further illustrates stigmator 727 applying a focusing effect that focuses primary electron beam 705, it is appreciated that stigmator 727 may apply any focusing effect to manipulate primary electron beam 705 to adjust a probe current. In some embodiments, a subset of deflectors (such as 533d or 533e, or both, in FIG. 5) may be used as an electrostatic lens in combination with stigmator 727 to compensate focus of primary electron beam 705 when a probe current is varied.

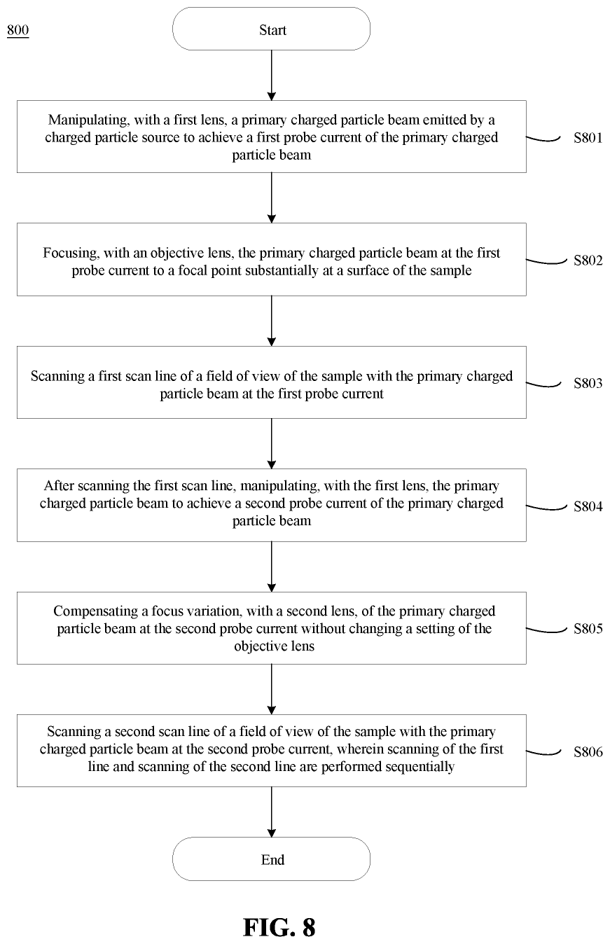

Reference is now made to FIG. 8, which is a flowchart representing an example process for compensating electron beam focus, consistent with embodiments of the present disclosure. The steps of method 800 may be performed by a charged particle beam apparatus such as a SEM, for example, described above with respect to FIGS. 5,6, and 7, executing on or otherwise using the features of a computing device (e.g., controller 109 of FIG. 1). It is appreciated that the illustrated method 800 may be altered to modify the order of steps and to include additional steps.

Method 800 is a process for determining electrical characteristics of a sample device without direct contact to the sample using a primary charged particle beam, such as a SEM. The sample device may be scanned multiple times with a primary charged particle beam at different probe currents or landing energies. As a result of changing the probe current, the primary charged particle beam may be over-focused or under-focused. Adjusting focus using a magnetic objective lens may decrease throughput, so the primary charged particle beam may be focus compensated with an additional component of a charged particle beam apparatus such as a SEM. Images generated by emitted secondary charged particles from the primary charged particle beam at different probe currents or landing energies may be used to back calculate electrical characteristics of the sample device.

In step S801, a first lens may manipulate a primary charged particle beam (such as primary electron beam 505 in FIG. 5) emitted by a charged particle source (such as cathode 503 in FIG. 5) to achieve a first probe current of the primary charged particle beam. In some embodiments, the first probe current may be selected such that a yield of emitted secondary charged particles is greater than 1 (such as the yield of emitted secondary electrons in FIG. 3). In some embodiments, the first lens may manipulate the primary charged particle beam by applying a focusing effect to the primary charged particle beam to achieve a first probe current. In some embodiments, the first lens is communicatively coupled with a controller (such as controller 109 in FIG. 1) in which an electrical signal is applied to the first lens to manipulate the primary charged particle beam. In some embodiments, the first lens may be a condenser lens as explained above with respect to FIG. 5. In some embodiments, the condenser lens may be a magnetic, electrostatic, or compound magnetic and electro-static lens. In some embodiments, the first lens may be a stigmator lens as explained above with respect to FIG. 7. In some embodiments, the stigmator lens may be an electrostatic lens.

In step S802, the primary charged particle beam at the first probe current may be focused with an objective lens (such as objective lens 532 in FIG. 5) to a focal point substantially at a surface of a sample (such as sample 550 in FIG. 5). In some embodiments, the objective lens may be communicatively coupled with a processor that may apply an electrical signal to the objective lens to focus the primary charged particle beam at the first probe current. In some embodiments, the processor may record the strength of the electrical signal applied to the objective lens.

In step S803, the primary charged particle beam at the first probe current may be deflected by deflectors (such as deflectors 533a-533e in FIG. 5) to scan a first scan line across of field of view on the surface of the sample for a time interval. In some embodiments, the time interval may be 10 μs to 100 μs, inclusive as explained above with respect to FIG. 6. In some embodiments, the primary charged particle beam at the first probe current may be scanned across the surface of the sample using the deflectors. In some embodiments, the primary charged particle beam at the first probe current may be scanned across one line on the sample. In some embodiments, the primary charged particle beam at the first probe current may be scanned across a plurality of lines on the sample. The primary charged particle beam at the first probe current scanned across the sample may result in a sample charge difference (such as sample voltage difference 420 in FIG. 4) and generate a sample current (such as sample current 410 in FIG. 4).

In step S804, after scanning the first scan line, settings of the first lens may be changed to manipulate the primary charged particle beam to achieve a second probe current of the primary charged particle beam. The second probe current may be different from the first probe current. The first lens may manipulate the primary charged particle beam to achieve a second probe current as described above. The second probe current may be selected such that a yield of emitted secondary charged particles is greater than 1. This may result in a different surface of the sample and generate a different sample voltage difference (such as sample voltage difference 420 in FIG. 4) and sample current (such as sample current 410 in FIG. 4).

In step S805, a primary charged particle beam at the second probe current may be compensated for a focus variation using a second lens, without changing a setting of the objective lens (such as objective lens 532 in FIG. 5). As described above, increasing or decreasing the probe current may cause a focus variation (e.g., over-focus or under-focus). As explained with respect to FIG. 5 above, a deflector (such as deflector 533d) may be used for compensation. Similarly, one or more of deflectors (such as deflectors 533d and 533e) may be used for compensation. During this step, the same electrical signal applied in step S803 by the processor may be applied to the objective lens because adjusting the setting of the objective lens may take a long time in comparison. In some embodiments, the second lens may be one or more deflectors, each comprising a plurality of electrodes, used separately or in combination. In some embodiments, the second lens may be an electrostatic lens. In some embodiments, the second lens may be communicatively coupled with a processor in which an electrical signal may be applied to all electrodes of the plurality of electrodes comprising the deflector. In some embodiments, a same electrical signal may be applied to all electrodes of the plurality of electrodes comprising the deflector. In some embodiments, the focusing function of the deflector may not interfere with the deflection function of the deflector.

In step S806, the primary charged particle beam at the second probe current may be deflected by deflectors (such as deflectors 533a-533e in FIG. 5) to scan a second scan line across of field of view on the surface of the sample for a time interval. The primary charged particle beam at the second probe current may be scanned across the sample as described in the embodiments referenced in step S803 above. The primary charged particle beam at the second probe current scanned across the sample may result in a different surface charge of a sample and generate a different sample current.

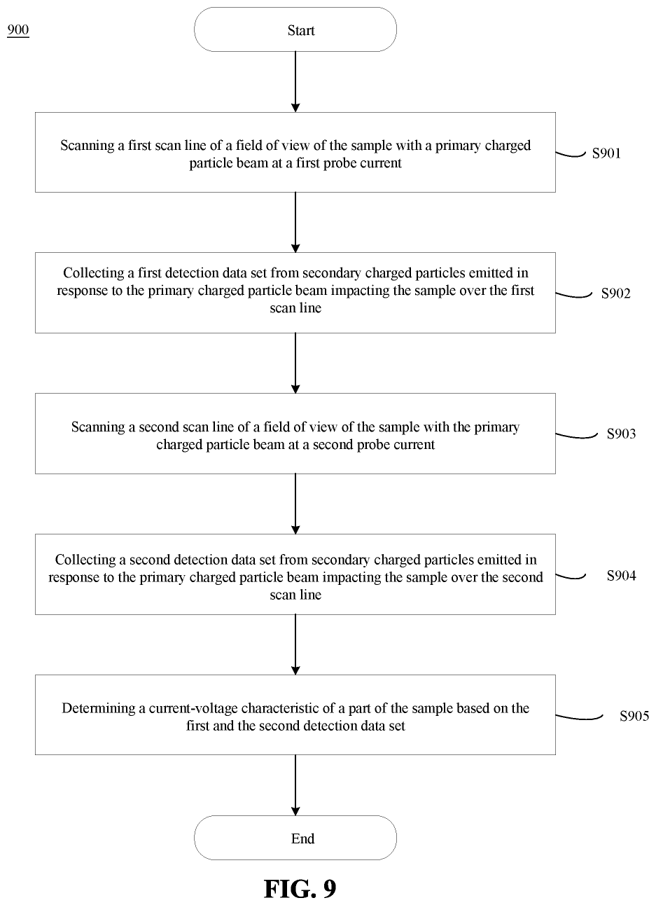

Reference is now made to FIG. 9, which is a flowchart representing an example process for determining an electrical characteristic of a sample without direct contact, consistent with embodiments of the present disclosure. The steps of method 900 may be performed by a charged particle beam apparatus such as a SEM, for example, described above with respect to FIGS. 5, 6, and 7, executing on or otherwise using the features of a computing device (e.g., controller 109 of FIG. 1). It is appreciated that the illustrated method 900 may be altered to modify the order of steps and to include additional steps.

In step S901, a primary charged particle beam at a first probe current may be scanned in a first scan line across a field of view on a surface of a sample for a time interval. Before scanning, the primary charged particle beam may have been manipulated to achieve the first probe current (e.g., according to step S801 of FIG. 8) and compensated for the focus variation (e.g., according to step S802 of FIG. 8). The primary charged particle beam at the first probe current may be scanned across the sample as described in the embodiments detailed above (e.g., according to descriptions above for FIG. 6).

In step S902, a detector may collect a first detection data set from secondary charged particles emitted in response to the primary charged particle beam at the first probe current impacting the sample over the first scan line. In some embodiments, the first detection data set may comprise a current of secondary charged particles emitted in response to the primary charged particle beam at the first probe current impacting the sample over the first scan line. In some embodiments, the first detection data set may correspond to the first probe current selected for the primary charged particle beam, an accumulated surface charge to generate a voltage difference (such as sample voltage difference 420 in FIG. 4), and a sample current (such as sample current 410 in FIG. 4).

In step S903, the primary charged particle beam at a second probe current may be scanned in a second scan line across a field of view on the surface of the sample for a time interval. Before scanning, the primary charged particle beam may have been manipulated to achieve the second probe current (e.g., according to step S804 of FIG. 8) and compensated for the focus variation (e.g., according to step S805 of FIG. 8). The primary charged particle beam at the second probe current may be scanned across the sample as described in embodiments detailed above (e.g., according to descriptions above for FIG. 6).

In step S904, the detector may collect a second detection data set from secondary charged particles emitted in response to the primary charged particle beam at the second probe current impacting the sample over the second scan line. In some embodiments, the second detection data set may comprise a current of secondary charged particles emitted in response to the primary charged particle beam at the second probe current impacting the sample over the second scan line. In some embodiments, the second detection data set may correspond to the second probe current selected for the primary charged particle beam, an accumulated surface charge to generate a voltage difference (such as sample voltage difference 420 in FIG. 4), and a sample current (such as sample current 410 in FIG. 4).

In step S905, an electrical characteristic of a part of the sample may be determined based on the first and second detection data set. In some embodiments, the electrical characteristic may be a current-voltage characteristic (e.g., resistance or capacitance).

A non-transitory computer readable medium may be provided that may store instructions for a processor of a controller (e.g., controller 109 of FIG. 1) to perform inspection image acquisition, stage positioning, primary charged particle beam focusing and compensation, inspection of electrical characteristics of sample devices, electrostatic field adjustments, objective lens adjusting, activating charged particle source, method 800 of FIG. 8, method 900 of FIG. 9, and other executable functions in the charged particle system relating to the primary charged particle beam focus compensation and contactless nano-probe method. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A charged particle beam apparatus for inspecting a sample, comprising:
   a charged particle source configured to emit a primary charged particle beam;
   a first lens configured to manipulate the primary charged particle beam to adjust a probe current of the primary charged particle beam;
   an objective lens configured to focus the primary charged particle beam to a focal point substantially on a surface of the sample;
   a second lens configured to generate an electrostatic field that substantially overlaps with a magnetic field generated by the objective lens and also to compensate for a focus variation caused by a change in probe current without changing a focusing power of the objective lens, wherein the change in probe current is caused by the first lens; and
   a deflector configured to deflect the primary charged particle beam to scan a scan line of a field of view of the sample.
2. The apparatus of clause 1, wherein the first lens is a magnetic lens.
3. The apparatus of clause 1, wherein the first lens is an electrostatic lens.
4. The apparatus of clause 1, wherein the first lens is a compound magnetic and electrostatic lens.
5. The apparatus of clauses 3 or 4, wherein the first lens comprises a plurality of electrodes.
6. The apparatus of clause 5, wherein an electrical signal is applied to the plurality of electrodes.
7. The apparatus of any one of clauses 1-4, wherein the first lens is a condenser lens.
8. The apparatus of any one of clauses 1-4, wherein the first lens is a stigmator.
9. The apparatus of clause 1, wherein the second lens is an electrostatic lens.
10. The apparatus of clause 9, wherein the second lens comprises a plurality of electrodes.
11. The apparatus of clause 10, wherein an electrical signal is applied to the plurality of electrodes.
12. The apparatus of clause 11, wherein a same electrical signal is applied to all electrodes of the plurality of electrodes.
13. The apparatus of clause 1, wherein the second lens is a deflector.
14. The apparatus of clause 1, further comprising a charged particle detector configured to collect charged particle data from secondary charged particles emitted in response to the primary charged particle beam impacting the sample.
15. The apparatus of clause 14, wherein the charged particle detector includes circuity configured to determine an electrical characteristic of the sample based on the collected charged particle data without direct contact with the sample.
16. A charged particle beam apparatus for inspecting a sample, comprising:
   a charged particle source configured to emit a primary charged particle beam;
   a first lens configured to manipulate the primary charged particle beam to adjust a probe current level of the primary charged particle beam;
   an objective lens configured to focus the primary charged particle beam to a focal point substantially on a surface of the sample; and
   a plurality of deflectors configured to deflect the primary charged particle beam to scan a scan line of a field of view of the sample, wherein a subset of the plurality of deflectors are further configured to generate an electrostatic field that substantially overlaps with a magnetic field generated by the objective lens and also to compensate for a focus variation caused by a change in probe current level, wherein the change in probe current level is caused by the first lens.
17. The apparatus of clause 16, wherein the first lens is a magnetic lens.
18. The apparatus of clause 16, wherein the first lens is an electrostatic lens.
19. The apparatus of clause 16, wherein the first lens is a compound magnetic and electrostatic lens.
20. The apparatus of clauses 18 or 19, wherein the first lens comprises a plurality of electrodes.
21. The apparatus of clause 20, wherein an electrical signal is applied to the plurality of electrodes.
22. The apparatus of any one of clauses 16-19, wherein the first lens is a condenser lens.
23. The apparatus of any one of clauses 16-19, wherein the first lens is a stigmator.
24. The apparatus of clause 16, wherein the subset of the plurality of deflectors are electrostatic lenses.
25. The apparatus of clause 24, wherein each deflector of the subset of the plurality of deflectors comprises a plurality of electrodes.
26. The apparatus of clause 25, wherein an electrical signal is applied to the plurality of electrodes.
27. The apparatus of clause 26, wherein a same electrical signal is applied to all electrodes of the plurality of electrodes.
28. A method of adjusting focus of a charged particle beam to inspect a sample, comprising:
   manipulating, with a first lens, a primary charged particle beam emitted by a charged particle source to change a current of the primary charged particle beam to a first probe current;
   focusing, with an objective lens, the primary charged particle beam at the first probe current to a focal point substantially at a surface of the sample;
   scanning a first scan line of a field of view of the sample with the primary charged particle beam at the first probe current;
   after scanning the first scan line, manipulating, with the first lens, the primary charged particle beam to change the current of the primary charged particle beam to a second probe current;
   compensating, with a second lens, a focus variation, with a second lens, of the primary charged particle beam at the second probe current without changing a setting of the objective lens; and
   scanning a second scan line of a field of view of the sample with the primary charged particle beam at the second probe current, wherein scanning of the first line and scanning of the second line are performed sequentially.
29. The method of clause 28, wherein the first lens is a magnetic lens.
30. The method of clause 28, wherein the first lens is an electrostatic lens.
31. The method of clause 28, wherein the first lens is a compound magnetic and electrostatic lens.
32. The method of clauses 30 or 31, wherein the first lens comprises a plurality of electrodes.
33. The method of clause 32, further comprising applying an electric signal to the plurality of electrodes.
34. The method of any one of clauses 28-31, wherein the first lens is a condenser lens.
35. The method of any one of clauses 28-31, wherein the first lens is a stigmator.
36. The method of clause 28, wherein the second lens is an electrostatic lens.
37. The method of clause 36, wherein the second lens comprises a plurality of electrodes.
38. The method of clause 37, further comprising applying electrical signal to the plurality of electrodes.
39. The method of clause 38, further comprising applying a same electrical signal to all electrodes of the plurality of electrodes.
40. The method of clause 28, wherein the second lens is a deflector.
41. The method of clause 28, further comprising:
   collecting charged particle detection data from secondary charged particles emitted in response to the primary charged particle beam at the first probe current impacting the sample; and
   collecting charged particle detection data from secondary charged particles emitted in response to the primary charged particle beam at the second probe current impacting the sample.
42. The method of clause 41, further comprising determining an electrical characteristic of the sample based on the charged particle detection data from the primary charged particle beam at the first probe current and the second probe current impacting the sample.
43. The method of clause 28, wherein scanning of the first line and scanning of the second line are performed sequentially with no intervening scan of any other line having happened.
44. A method of inspecting a sample using a charged particle beam apparatus configured to direct a charged particle beam onto the sample, the method comprising:
   scanning a first scan line of a field of view of the sample with the charged particle beam at a first probe current;
   collecting a first detection data set from secondary charged particles emitted in response to the charged particle beam impacting the sample over the first scan line;
   scanning a second scan line of a field of view of the sample with the charged particle beam at a second probe current, wherein scanning of the first scan line and scanning of the second scan line are performed sequentially;
   collecting a second detection data set from secondary charged particles emitted in response to the charged particle beam impacting the sample over the second scan line; and
   determining a current-voltage characteristic of a part of the sample based on the first and the second detection data set.
45. The method of clause 44, wherein scanning of the first scan line and scanning of the second scan line are performed sequentially with no intervening scan of any other line having happened.
46. The method of clause 44, wherein the current-voltage characteristic is a resistance or capacitance of the sample.
47. The method of clause 44, further comprising identifying a sample defect by comparing the current-voltage characteristic to an expected current-voltage characteristic of the part of the sample.
48. A non-transitory computer readable medium storing a set of instructions that is executable by one or more processors of a charged particle beam apparatus to cause the charged particle beam apparatus to perform a method of inspecting a sample, the method comprising:
   manipulating, with a first lens, a primary charged particle beam emitted by a charged particle source to change a current of the primary charged particle beam to a first probe current;
   focusing, with an objective lens, the primary charged particle beam at the first probe current to a focal point substantially at a surface of the sample;
   scanning a first scan line of a field of view of the sample with the primary charged particle beam at the first probe current;
   after scanning the first scan line, manipulating, with the first lens, the primary charged particle beam to change the current of the primary charged particle beam to a second probe current;
   compensating, with a second lens, a focus variation, with a second lens, of the primary charged particle beam at the second probe current without changing a setting of the objective lens; and
   scanning a second scan line of a field of view of the sample with the primary charged particle beam at the second probe current, wherein scanning of the first line and scanning of the second line are performed sequentially.
49. The non-transitory computer readable medium of clause 48, wherein scanning of the first line and scanning of the second line are performed sequentially with no intervening scan of any other line having happened.
50. The non-transitory computer readable medium of clause 48, wherein the first lens is a magnetic lens.
51. The non-transitory computer readable medium of clause 48, wherein the first lens is an electrostatic lens.
52. The non-transitory computer readable medium of clause 48, wherein the first lens is a compound magnetic and electrostatic lens.
53. The non-transitory computer readable medium of clauses 51 or 52, wherein the first lens comprises a plurality of electrodes.
54. The non-transitory computer readable medium of clause 53, wherein an electrical signal is applied to the plurality of electrodes.
55. The non-transitory computer readable medium of any one of clauses 48-52, wherein the first lens is a condenser lens.
56. The non-transitory computer readable medium of any one of clauses 48-52, wherein the first lens is a stigmator.
57. The non-transitory computer readable medium of clause 48, wherein the second lens is an electrostatic lens.
58. The non-transitory computer readable medium of clause 57, wherein the second lens comprises a plurality of electrodes.
59. The non-transitory computer readable medium of clause 58, wherein an electrical signal is applied to the plurality of electrodes.
60. The non-transitory computer readable medium of clause 59, wherein a same electrical signal is applied to all electrodes of the plurality of electrodes.
61. The non-transitory computer readable medium of clause 48, wherein the second lens is a deflector.
62. The non-transitory computer readable medium of clause 48, wherein the set of instructions that is executable by the one or more processors to cause the charged particle beam apparatus to further perform:
   collecting charged particle detection data from secondary charged particles emitted in response to the primary charged particle beam at the first probe current impacting the sample; and
   collecting charged particle detection data from secondary charged particles emitted in response to the primary charged particle beam at the second probe current impacting the sample.
63. The non-transitory computer readable medium of clause 62, wherein the set of instructions that is executable by the one or more processors to cause the charged particle beam apparatus to further perform determining an electrical characteristic of the sample based on the charged particle detection data from the primary charged particle beam at the first probe current and the second probe current impacting the sample.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A charged particle beam apparatus for inspecting a sample, comprising:
a charged particle source configured to emit a primary charged particle beam;
a first lens configured to manipulate the primary charged particle beam to adjust a probe current of the primary charged particle beam;
an objective lens configured to focus the primary charged particle beam to a focal point substantially on a surface of the sample;
a second lens configured to generate an electrostatic field that substantially overlaps with a magnetic field generated by the objective lens and also to compensate for a focus variation caused by a change in probe current without changing a focusing power of the objective lens, wherein the change in probe current is caused by the first lens; and
a deflector configured to deflect the primary charged particle beam to scan a scan line of a field of view of the sample.

2. The apparatus of claim 1, wherein the first lens is a magnetic lens.

3. The apparatus of claim 1, wherein the first lens is an electrostatic lens.

4. The apparatus of claim 1, wherein the first lens is a compound magnetic and electrostatic lens.

5. The apparatus of claim 3, wherein the first lens comprises a plurality of electrodes.

6. The apparatus of claim 5, wherein an electrical signal is applied to the plurality of electrodes.

7. The apparatus of claim 1, wherein the first lens is a condenser lens.

8. The apparatus of claim 1, wherein the first lens is a stigmator.

9. The apparatus of claim 1, wherein the second lens is an electrostatic lens.

10. The apparatus of claim 9, wherein the second lens comprises a plurality of electrodes.

11. The apparatus of claim 10, wherein an electrical signal is applied to the plurality of electrodes.

12. The apparatus of claim 11, wherein a same electrical signal is applied to all electrodes of the plurality of electrodes.

13. The apparatus of claim 1, wherein the second lens is a deflector.

14. The apparatus of claim 1, further comprising a charged particle detector configured to collect charged particle data from secondary charged particles emitted in response to the primary charged particle beam impacting the sample wherein the charged particle detector includes circuity configured to determine an electrical characteristic of the sample based on the collected charged particle data without direct contact with the sample.

15. A non-transitory computer readable medium storing a set of instructions that is executable by one or more processors of a charged particle beam apparatus to cause the charged particle beam apparatus to perform a method of inspecting a sample, the method comprising:
manipulating, with a first lens, a primary charged particle beam emitted by a charged particle source to change a current of the primary charged particle beam to a first probe current;
focusing, with an objective lens, the primary charged particle beam at the first probe current to a focal point substantially at a surface of the sample;
scanning a first scan line of a field of view of the sample with the primary charged particle beam at the first probe current;
after scanning the first scan line, manipulating, with the first lens, the primary charged particle beam to change the current of the primary charged particle beam to a second probe current;
compensating, with a second lens, a focus variation of the primary charged particle beam at the second probe current without changing a setting of the objective lens; and
scanning a second scan line of the field of view of the sample with the primary charged particle beam at the second probe current, wherein scanning of the first line and scanning of the second line are performed sequentially.

16. A charged particle beam apparatus for inspecting a sample, comprising:
a charged particle source configured to emit a primary charged particle beam;
a first lens configured to manipulate the primary charged particle beam to adjust a probe current level of the primary charged particle beam;
an objective lens configured to focus the primary charged particle beam to a focal point substantially on a surface of the sample; and
a plurality of deflectors configured to deflect the primary charged particle beam to scan a scan line of a field of view of the sample, wherein a subset of the plurality of deflectors are further configured to generate an electrostatic field that substantially overlaps with a magnetic field generated by the objective lens and also to compensate for a focus variation caused by a change in probe current level, wherein the change in probe current level is caused by the first lens.

17. The apparatus of claim 16, wherein the first lens is a magnetic lens, or an electrostatic lens, or a compound magnetic and electrostatic lens.

18. The apparatus of claim 16, wherein the first lens comprises a plurality of electrodes.

19. The apparatus of claim 16, wherein the subset of the plurality of deflectors are electrostatic lenses.

20. The apparatus of claim 19, wherein each deflector of the subset of the plurality of deflectors comprises a plurality of electrodes and a same electrical signal is applied to all electrodes of the plurality of electrodes.
